(19) United States
(12) Patent Application Publication
(10) Pub. No.: US 2012/0299046 A1
(43) Pub. Date: Nov. 29, 2012

(54) SEMICONDUCTOR LIGHT EMITTING DEVICE AND METHOD FOR MANUFACTURING SAME

(75) Inventor: Shuji Itonaga, Kanagawa-ken (JP)

(73) Assignee: KABUSHIKI KAISHA TOSHIBA, Tokyo (JP)

(21) Appl. No.: 13/316,666

(22) Filed: Dec. 12, 2011

(30) Foreign Application Priority Data
May 26, 2011 (JP) 2011-117987

(51) Int. Cl. H01L 33/42

(52) U.S. Cl. 257/99; 438/22; 257/E33.064

(57) ABSTRACT

According to one embodiment, a semiconductor light emitting device includes a first semiconductor layer of a first conductivity type, a light emitting layer, a second semiconductor layer of a second conductivity type, a first electrode layer and a second electrode layer. The first semiconductor layer includes a first portion and a second portion thicker than the first portion. The second portion includes a side surface rising from a major surface of the first portion. The light emitting layer is provided on the second portion. The second semiconductor layer is provided on the light emitting layer. The first electrode layer is provided along the major surface of the first portion and is in contact with the side surface of the second portion. The second electrode layer is provided on the second semiconductor layer.

### CROSS-REFERENCE TO RELATED APPLICATIONS

This application is based upon and claims the benefit of priority from the prior Japanese Patent Application No. 2011-117987, filed on May 26, 2011; the entire contents of which are incorporated herein by reference.

### FIELD

Embodiments described herein relate generally to a semiconductor light emitting device and a method for manufacturing the same.

### BACKGROUND

Semiconductor light emitting devices such as LEDs (light emitting diodes) are based on the technique for forming a stacked body including a light emitting layer on a substrate. In semiconductor light emitting devices, as an electrode formed on the light outgoing surface (extraction surface), a metal material or a transparent electrode made of e.g. ITO (indium tin oxide) is used. In such semiconductor light emitting devices, there is demand for further improvement in light emission efficiency and simplification of the manufacturing process.

### BRIEF DESCRIPTION OF THE DRAWINGS

FIGS. 1 A and 1B are schematic views illustrating the configuration of a semiconductor light emitting device according to an embodiment;

FIG. 2 illustrates the relationship between the area of the light emitting region and the optical output;

FIGS. 3A to 4C are schematic sectional views illustrating a manufacturing method according to the embodiment;

FIGS. 5A and 5B illustrate the state before and after etching of the electrode material;

FIG. 6 is a schematic sectional view illustrating the configuration of a semiconductor light emitting device according to an embodiment;

FIGS. 7A to 8B are schematic sectional views illustrating a manufacturing method according to the embodiment; and

FIGS. 9A and 9B are schematic views illustrating the configuration of a semiconductor light emitting device according to an embodiment.

### DETAILED DESCRIPTION

In general, according to one embodiment, a semiconductor light emitting device includes a first semiconductor layer of a first conductivity type, a light emitting layer, a second semiconductor layer of a second conductivity type, a first electrode layer and a second electrode layer. The first semiconductor layer includes a first portion and a second portion thicker than the first portion. The second portion includes a side surface rising from a major surface of the first portion. The light emitting layer is provided on the second portion. The second semiconductor layer is provided on the light emitting layer. The first electrode layer is provided along the major surface of the first portion and is in contact with the side surface of the second portion. The second electrode layer is provided on the second semiconductor layer.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the specification and the drawings, components similar to those described previously with reference to earlier figures are labeled with like reference numerals, and the detailed description thereof is omitted as appropriate.

In the following description, by way of example, it is assumed that the first conductivity type is n-type and the second conductivity type is p-type.

### First Embodiment

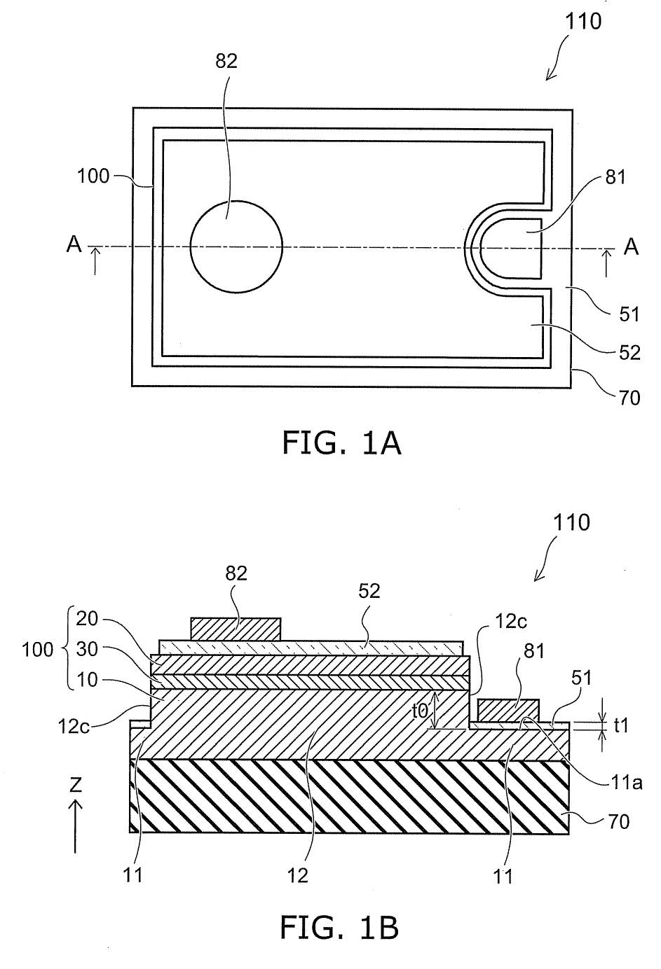

FIGS. 1A and 1B are schematic views illustrating the configuration of a semiconductor light emitting device according to a first embodiment.

More specifically, FIG. 1A is a schematic plan view of the semiconductor light emitting device 110 according to the embodiment. FIG. 1B is a schematic sectional view taken along line A-A shown in FIG. 1A.

As shown in FIGS. 1A and 1B, the semiconductor light emitting device 110 according to the first embodiment includes a first semiconductor layer 10, a light emitting layer 30, a second semiconductor layer 20, a first electrode layer 51, and a second electrode layer 52.

The first semiconductor layer 10, the light emitting layer 30, and the second semiconductor layer 20 are sequentially stacked to form a stacked body 100. In the semiconductor light emitting device 110, the stacked body 100 constitutes a light emitting region. The stacked body 100 is made of e.g. nitride semiconductors. The semiconductor light emitting device 110 is e.g. an LED emitting blue light.

In the specification, the “nitride semiconductor” includes semiconductors having any composition represented by the chemical formula InₓAl_{y}Ga_{1-x-y}N (0≦x≦1, 0≦y≦1, x+y≦1) or BₓIn_{y}Al_{z}Ga_{1-x-y-z}N (0≦x≦1, 0≦y≦1, 0≦z≦1, x+y+z≦1) where the composition ratios x, y, and z are varied in the respective ranges. Furthermore, in the above chemical formulas, the “nitride semiconductor” also includes those further containing any group V element other than N (nitrogen), those further containing various elements added for controlling various material properties such as conductivity type, and those further containing various unintended elements.

In the specification, the direction connecting the first semiconductor layer 10 and the second semiconductor layer 20 is referred to as Z-axis direction. In the Z-axis direction, the second semiconductor layer 20 side as viewed from the first semiconductor layer 10 is referred to as upper side (or also simply referred to as “above”).

The first semiconductor layer 10 is a semiconductor layer of the first conductivity type. That is, the first semiconductor layer 10 is e.g. an n-type nitride semiconductor layer.

The first semiconductor layer 10 includes a first portion 11 and a second portion 12.

The first portion 11 is a portion where the stacked body 100 is partly removed. For instance, the first portion 11 is a portion where the thickness along the Z-axis direction of the first semiconductor layer 10 is thinned by partly removing the stacked body 100 from the second semiconductor layer 20 to halfway through the first semiconductor layer 10 (mesa etching). The first semiconductor layer 10 is exposed at the major surface 11a of the first portion 11.

The second portion 12 is a portion where the thickness along the Z-axis direction is thicker than the first portion 11. For instance, the second portion 12 is a portion of the first semiconductor layer 10 left unremoved in the mesa etching of the stacked body 100.

The second portion 12 includes a side surface 12c rising from the major surface 11a of the first portion 11.

The light emitting layer 30 is provided on the second portion 12 of the first semiconductor layer 10.

The light emitting layer 30 is formed from e.g. nitride semiconductors. The light emitting layer 30 is based on e.g. a multiple quantum well structure in which well layers and barrier layers are alternately stacked.

The second semiconductor layer 20 is provided on the light emitting layer 30. The second semiconductor layer 20 is a semiconductor layer of the second conductivity type. The second semiconductor layer 20 is e.g. a p-type nitride semiconductor layer.

In the semiconductor light emitting device 110 according to the embodiment, the first semiconductor layer 10, the light emitting layer 30, and the second semiconductor layer 20 are formed by crystal growth on a substrate 70.

In the stacked body 100, the light emitting layer 30 is provided between the first semiconductor layer 10 and the second semiconductor layer 20. The stacked body 100 functions as a light emitting region of the semiconductor light emitting device 110.

In the semiconductor light emitting device 110 according to the embodiment, the first electrode layer 51 is provided along the major surface 11a of the first portion 11. The second electrode layer 52 is provided on the second semiconductor layer 20.

The first electrode layer 51 is provided in contact with the side surface 12c of the second portion 12. The first electrode layer 51 may be in contact with the entire periphery of the side surface 12c of the second portion 12, or may include a portion in contact with part of the side surface 12c. This can reduce the gap between the first electrode layer 51 and the side surface 12c of the second portion 12. In the semiconductor light emitting device 110 according to the embodiment, the light emitting region constituted by the stacked body 100 can be made larger than that in the case where the first electrode layer 51 is not in contact with the side surface 12c. For the same device size, the light emission efficiency can be increased by increasing the light emitting region.

On the first electrode layer 51, a first metal electrode 81 in contact with part of the first electrode layer 51 is provided. The first metal electrode 81 is e.g. an n-side pad electrode. Furthermore, on the second electrode layer 52, a second metal electrode 82 in contact with part of the second electrode layer 52 is provided. The second metal electrode 82 is e.g. a p-side pad electrode.

These pad electrodes are connected with wiring members such as bonding wires. A current is supplied from outside through this wiring member to the light emitting layer 30.

By passing a driving current from the second metal electrode 82 serving as a p-side pad electrode to the first metal electrode 81 serving as an n-side pad electrode, the semiconductor light emitting device 110 emits e.g. blue light in the light emitting region.

In the semiconductor light emitting device 110, the first electrode layer 51 and the second electrode layer 52 are electrically isolated from each other. That is, although the first electrode layer 51 is in contact with the side surface 12c of the second portion 12 of the first semiconductor layer 10, the first electrode layer 51 is not in electrical continuity with the second electrode layer 52.

Specifically, the thickness t1 of the first electrode layer 51 along the Z-axis direction is thinner than the thickness t0 along the Z-axis direction of the side surface 12c portion of the second portion 12. Here, the thicknesses t1 and t0 are thicknesses with reference to the major surface 11a of the first portion 11. Thus, the first electrode layer 51 is not brought into contact with the light emitting layer 30 and the second semiconductor layer 20 provided on the first semiconductor layer 10. Hence, the first electrode layer 51 is not in electrical continuity with the second electrode layer 52 provided on the second semiconductor layer 20.

In the semiconductor light emitting device 110, the first electrode layer 51 and the second electrode layer 52 are formed from a translucent material which transmits light emitted from the light emitting layer 30. The first electrode layer 51 and the second electrode layer 52 include e.g. indium tin oxide (ITO).

By using a translucent material made of e.g. ITO for the first electrode layer 51 and the second electrode layer 52, a current can be injected from a wide area of the first semiconductor layer 10 and the second semiconductor layer 20 into the light emitting layer 30. Thus, the light emission efficiency can be increased. Furthermore, the light emitted from the light emitting layer 30 is transmitted through the first electrode layer 51 and the second electrode layer 52 and efficiently extracted outside.

The first electrode layer 51 is formed so as to surround the stacked body 100. That is, the stacked body 100 formed like a mesa is surrounded with the exposed portion of the first semiconductor layer 10. The first electrode layer 51 is provided on this exposed portion of the first semiconductor layer 10. Thus, the first electrode layer 51 is formed so as to surround the stacked body 100. That is, as viewed in the Z-axis direction, the first electrode layer 51 is formed so as to surround the second electrode layer 52.

By providing the first electrode layer 51 so as to surround the stacked body 100, the current path directed from the second metal electrode 82 to the first metal electrode 81 can be spread. This can alleviate local current concentration. By spreading the current flow, uniform light emission can be realized in the semiconductor light emitting device 110.

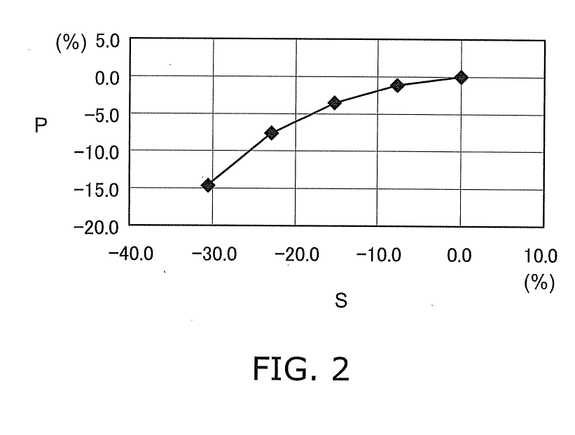

FIG. 2 illustrates the relationship between the scale factor of the area of the light emitting region and the rate of change of the optical output.

In FIG. 2, the horizontal axis represents the scale factor S (%) of the area of the light emitting region. The vertical axis represents the rate of change P (%) of the optical output.

FIG. 2 shows the rate of change of the optical output with respect to the shrinkage of the area of the light emitting region, where the scale factor S of the area of the light emitting region serving as a reference is defined as 0%, and the corresponding rate of change P of the optical output is defined as 0%.

It is found that the optical output decreases with the shrinkage of the area of the light emitting region.

Hence, for instance, if a gap is provided between the first electrode layer 51 and the side surface 12c of the second portion 12, and the area of the light emitting region is reduced, then the shrinkage of the area of the light emitting region results in decreasing the optical output.

In the semiconductor light emitting device 110 according to the embodiment, the first electrode layer 51 is provided in contact with the side surface 12c of the second portion 12. In the semiconductor light emitting device 110, the area of the light emitting region can be made larger than that in the semiconductor light emitting device in which a gap is provided between the first electrode layer 51 and the side surface 12c of the second portion 12. Thus, the brightness can be increased.

Next, an example method for manufacturing the semiconductor light emitting device 110 according to the first embodiment is described.

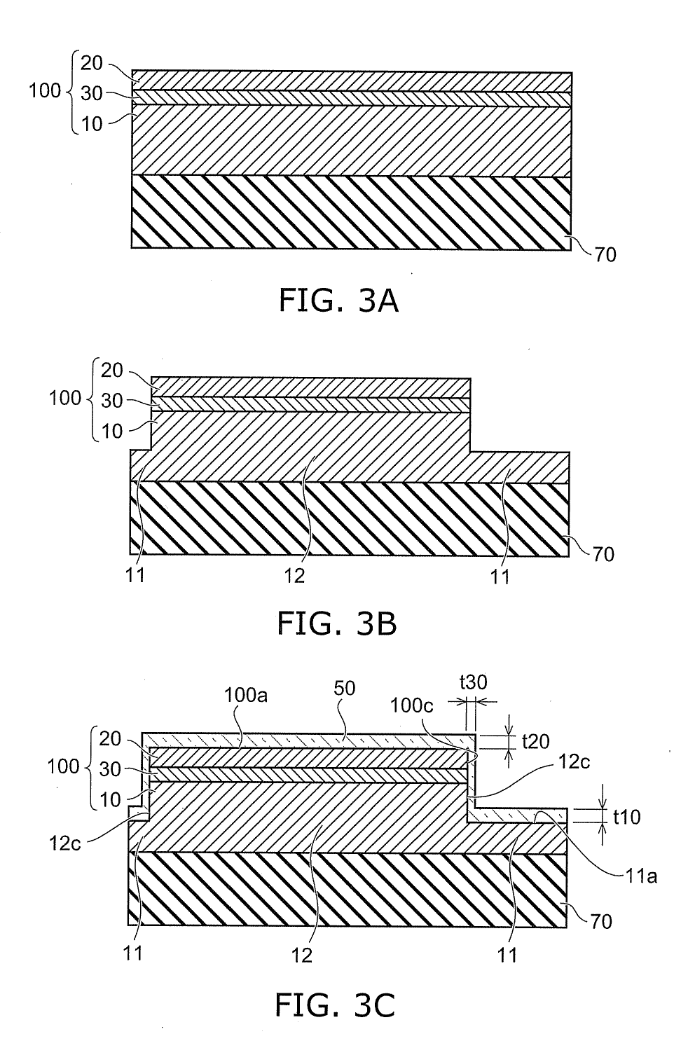

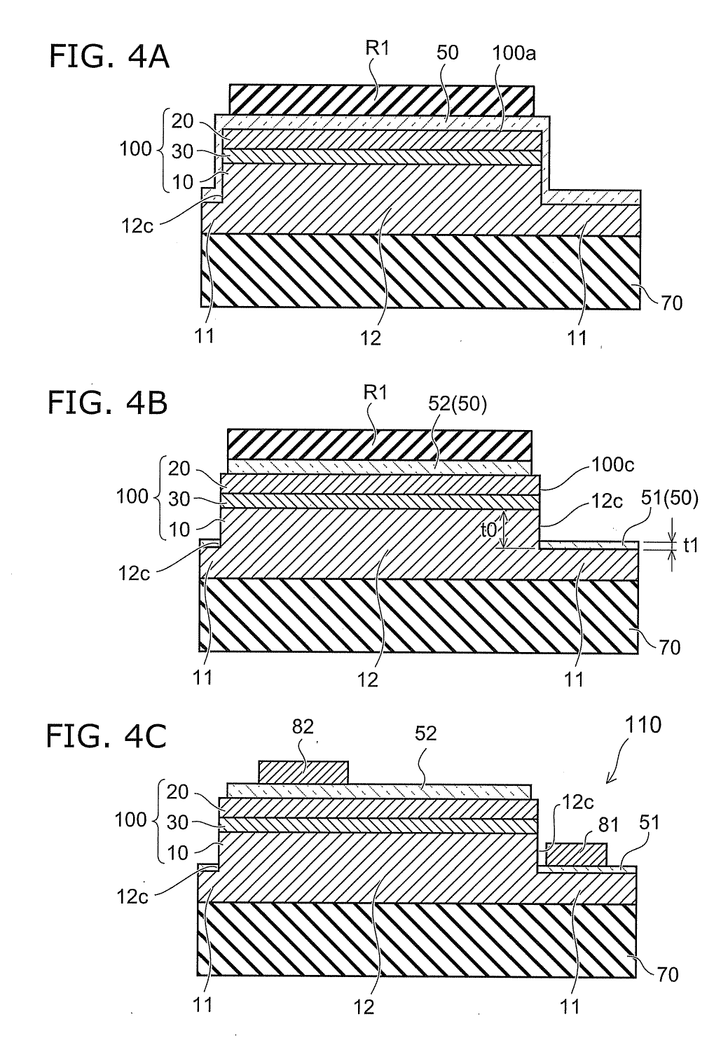

FIGS. 3A to 4C are schematic sectional views illustrating the method for manufacturing the semiconductor light emitting device.

First, as shown in FIG. 3A, a first semiconductor layer 10, a light emitting layer 30, and a second semiconductor layer 20 are sequentially formed on a substrate 70. The substrate 70 is e.g. a crystal growth substrate made of sapphire. The first semiconductor layer 10, the light emitting layer 30, and the second semiconductor layer 20 are formed by crystal growth on the substrate 70.

The stacked body 100 of the first semiconductor layer 10, the light emitting layer 30, and the second semiconductor layer 20 is formed by e.g. metal organic chemical vapor deposition. As an example, the stacked body 100 is made of nitride semiconductors.

For instance, a specific configuration and forming method of the stacked body 100 are as follows.

First, on a substrate 70 whose surface is made of sapphire c-plane, buffer layers are formed. As the buffer layers, a high carbon concentration first AlN buffer layer (e.g., with a carbon concentration of 3×10¹⁸ cm⁻³ or more and 5×10²⁰ cm⁻³ or less and a thickness of 3 nm or more and 20 nm or less), a high purity second AlN buffer layer (e.g., with a carbon concentration of e.g. 1×10¹⁶ cm⁻³ or more and 3×10¹⁸ cm⁻³ or less and a thickness of 2 μm), and a non-doped GaN buffer layer (e.g., with a thickness of 2 μm) are formed in this order. The above first and second AlN buffer layers are single crystal aluminum nitride layers. By using single crystal aluminum nitride layers for the first and second AlN buffer layers, high quality semiconductor layers can be formed in the crystal growth described below. This significantly reduces damage to the crystal.

Next, further thereon, a silicon-doped (Si-doped) n-type GaN contact layer (e.g., with a Si concentration of 1×10¹⁸ cm⁻³ or more and 5×10¹⁹ cm⁻³ or less and a thickness of 6 μm), and a Si-doped n-type Al_{0.10}Ga_{0.90}N cladding layer (e.g., with a Si concentration of 1×10¹⁸ cm⁻³ and a thickness of 0.02 μm) are sequentially formed in this order. The Si-doped n-type GaN contact layer and the Si-doped n-type Al_{0.10}Ga_{0.90}N cladding layer constitute the first semiconductor layer 10. Here, for convenience, all or part of the above buffer layers may be included in the first semiconductor layer 10.

Next, further thereon, as a light emitting layer 30, Si-doped n-type Al_{0.11}Ga_{0.89}N barrier layers and GaInN well layers are alternately stacked three periods. Furthermore, the final Al_{0.11}Ga_{0.89}N barrier layer of the multiple quantum well is stacked. In the Si-doped n-type Al_{0.11}Ga_{0.89}N barrier layer, for instance, the Si concentration is set to 1.1×10¹⁹ cm⁻³ or more and 1.5×10¹⁹ cm⁻³ or less. In the final Al_{0.11}Ga_{0.89}N barrier layer, for instance, the Si concentration is set to 1.1×10¹⁹ cm⁻³ or more and 1.5×10¹⁹ cm⁻³ or less, and the thickness is set to 0.01 μm. The thickness of this multiple quantum well structure is set to e.g. 0.075 μm. Subsequently, a Si-doped n-type Al_{0.11}Ga_{0.89}N layer (e.g., with a Si concentration of 0.8×10¹⁹ cm⁻³ or more and 1.0×10¹⁹ cm⁻³ or less and a thickness of 0.01 μm) is formed. Here, the wavelength of emission light in the light emitting layer 30 is e.g. 370 nm or more and 480 nm or less.

Furthermore, as a second semiconductor layer 20, a non-doped Al_{0.11}Ga_{0.89}N spacer layer (e.g., with a thickness of 0.02 μm), a Mg-doped p-type Al_{0.28}Ga_{0.72}N cladding layer (e.g., with a Mg concentration of 1×10¹⁹ cm⁻³ and a thickness of 0.02 μm), a Mg-doped p-type GaN contact layer (e.g., with a Mg concentration of 1×10¹⁹ cm⁻³ and a thickness of 0.4 μm), and a high concentration Mg-doped p-type GaN contact layer (e.g., with a Mg concentration of 5×10¹⁹ cm⁻³ and a thickness of 0.02 μm) are sequentially formed in this order.

Here, the compositions, the composition ratios, the kinds of impurities, the impurity concentrations, and the thicknesses described above are illustratively only, and can be variously modified.

Next, as shown in FIG. 3B, the stacked body 100 is selectively etched to form a mesa structure. In the embodiment, dry etching based on e.g. RIE (reactive ion etching) is used. In this etching, part of the stacked body 100 is removed from the second semiconductor layer 20 to halfway through the first semiconductor layer 10. The portion of the first semiconductor layer 10 exposed by etching constitutes a first portion 11. The portion of the first semiconductor layer 10 left unetched constitutes a second portion 12.

Next, as shown in FIG. 3C, an electrode material 50 is film-formed so as to entirely cover the surface of the stacked body 100 (the stacked portion left unetched) and the exposed portion of the first semiconductor layer 10. The electrode material 50 is a translucent material which transmits light emitted from the light emitting layer 30. In the embodiment, ITO is used as the electrode material 50.

The electrode material 50 made of ITO is film-formed by e.g. sputtering. The film thickness t30 of the film-formed electrode material 50 on the side surface 100c of the stacked body 100 (including the side surface 12c of the second portion 12) is thinner than the film thickness t20 on the upper surface 100a of the stacked body 100 and the film thickness t10 on the exposed major surface 11a of the first semiconductor layer 10. Here, the film thicknesses t10 and t20 are nearly equal.

The film thicknesses t10 and t20 are e.g. 100 nm or more and 300 nm or less.

The film thickness t30 is e.g. 30 nm or more and 150 nm or less.

Next, as shown in FIG. 4A, a resist pattern R1 is formed on the second semiconductor layer 20 constituting the upper surface 100a of the stacked body 100. The outer edge in the outline of the resist pattern R1 lies slightly inside the outer edge in the outline of the upper surface 100a. This is intended to ensure the subsequent etching allowing for the accuracy of photolithography.

Next, as shown in FIG. 4B, the resist pattern R1 is used as a mask to etch the electrode material 50. In this etching, for instance, wet etching is used. As an etchant for ITO, for instance, a liquid mixture of hydrochloric acid (HCl) and nitric acid (HNO₃) is used.

Here, in the etching of the electrode material 50, there is a difference between the etching rate of the electrode material 50 formed on the second semiconductor layer 20 and the etching rate of the electrode material 50 formed on the first semiconductor layer 10 exposed in the first portion 11.

Specifically, the etching rate of the electrode material 50 formed on the second semiconductor layer 20 is higher than the etching rate of the electrode material 50 formed on the first semiconductor layer 10.

Hence, the portion of the electrode material 50 on the second semiconductor layer 20 not covered with the resist pattern R1 is etched more rapidly than the electrode material 50 on the first semiconductor layer 10. Thus, even if this portion is removed, the electrode material 50 on the first semiconductor layer 10 is left.

Furthermore, the electrode material 50 formed on the side surface 100c of the stacked body 100 is thinner than the electrode material 50 on the first semiconductor layer 10, and hence is removed earlier than the electrode material 50 on the first semiconductor layer 10.

That is, this etching removes the electrode material 50 on the second semiconductor layer 20 not covered with the resist pattern R1 and the electrode material 50 formed on the side surface 100c of the stacked body 100. Thus, the electrode material 50 left on the first semiconductor layer 10 constitutes a first electrode layer 51, and the electrode material 50 on the second semiconductor layer 20 covered with the resist pattern R1 constitutes a second electrode layer 52. By the removal of the electrode material 50 formed on the side surface 100c, the first electrode layer 51 and the second electrode layer 52 are separated from each other.

Here, the state of etching of the electrode material 50 is described.

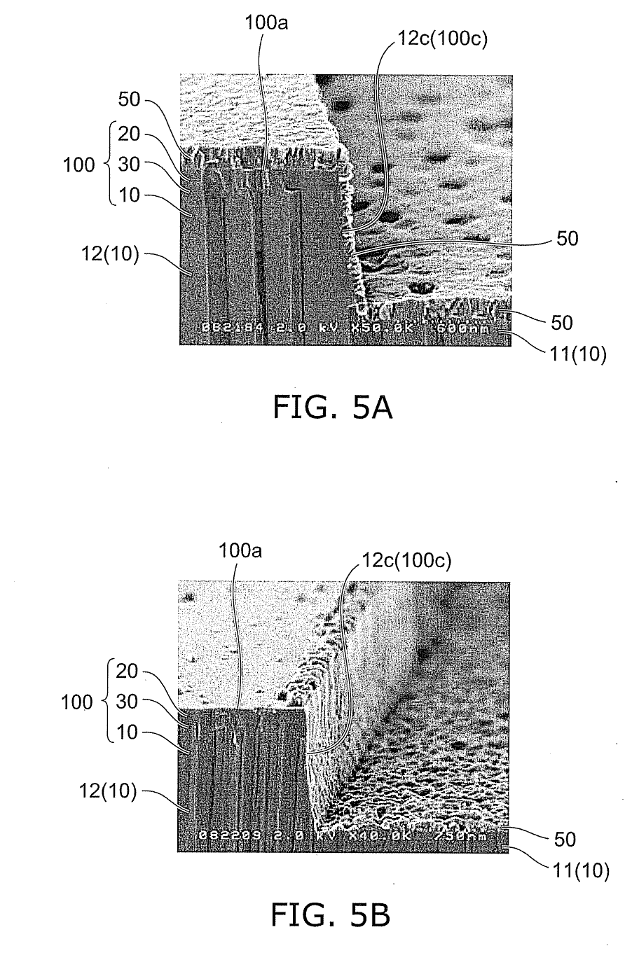

FIGS. 5A and 5B illustrate the state before and after etching of the electrode material (ITO).

More specifically, FIGS. 5A and 5B are electron micrographs illustrating the state before and after etching of the electrode material 50 formed on the first portion 11, the second portion 12, and the side surface 12c. FIG. 5A shows the state before etching, and FIG. 5B shows the state after etching.

As shown in FIG. 5A, the electrode material 50 is formed to a film thickness of approximately 170 nm on the first portion 11 of the first semiconductor layer 10 and on the second semiconductor layer 20. On the side surface 12c (100c), the electrode material 50 is formed to a film thickness of approximately 60 nm.

Wet etching of this electrode material 50 for a prescribed time results in the state as shown in FIG. 5B. That is, the electrode material 50 formed on the second semiconductor layer 20 and the side surface 12c (100c) is removed by etching, but the electrode material 50 formed on the first portion 11 of the first semiconductor layer 10 is left.

The difference in etching rate between the electrode material 50 on the first semiconductor layer 10 and the electrode material 50 on the second semiconductor layer 20 is attributable to differences in the surface state of the first semiconductor layer 10 and the second semiconductor layer 20.

Here, the differences in the surface state include e.g. the difference of dopants of the respective layers, the difference of impurity concentration, the difference of substances attached to the surface, and the difference of surface roughness.

In the embodiment, the surface of the first semiconductor layer 10 in the first portion 11 is the surface exposed by RIE of the stacked body 100. Hence, on this exposed surface of the first semiconductor layer 10, the gas used in the RIE (such as chlorine gas) is left. Furthermore, the surface roughness is made higher by the RIE on the surface of the first semiconductor layer 10 than on the surface of the second semiconductor layer 20. It is considered that such differences in the surface state cause the difference in the etching rate of the electrode material 50 film-formed thereon.

In the embodiment, by using such difference in etching rate, the electrode material 50 is separated into a first electrode layer 51 and a second electrode layer 52 by a single etching process. That is, while leaving the first electrode layer 51, the first electrode layer 51 can be separated from the second electrode layer 52.

Furthermore, the electrode material 50 formed on the side surface 12c (100c) is thinner than the electrode material 50 formed on the first semiconductor layer 10 and the second semiconductor layer 20, and hence is removed by etching. By such etching, the first electrode layer 51 and the second electrode layer 52 can be formed without the need of separate manufacturing processes.

As shown in FIG. 4B, the first electrode layer 51 left after etching the electrode material 50 is in contact with the side surface 12c along the major surface 11a. That is, the electrode material 50 on the first semiconductor layer 10 is reduced only in thickness, with the area left unchanged. Hence, the first electrode layer 51 is formed substantially entirely on the surface of the first semiconductor layer 10 exposed by etching the stacked body 100. For instance, the first electrode layer 51 is formed without any gap to the side surface 12c, and is formed so as to surround the stacked body 100.

The thickness of the first electrode layer 51 formed by this etching is t1. The thickness t1 is thinner than the thickness t0 of the side surface 12c portion of the second portion 12. Hence, even if the first electrode layer 51 is in contact with the side surface 12c, the first electrode layer 51 is not in contact with the light emitting layer 30 and the second semiconductor layer 20 formed on the second portion 12.

After etching the electrode material 50, the resist pattern R1 is removed.

Subsequently, as shown in FIG. 4C, a first metal electrode 81 is formed on the first electrode layer 51, and a second metal electrode 82 is formed on the second electrode layer 52. Thus, the semiconductor light emitting device 110 is completed.

This manufacturing method can form the first electrode layer 51 and the second electrode layer 52 by a single etching process, and can simplify the manufacturing process of the semiconductor light emitting device 110. Furthermore, the gap between the side surface 12c of the second portion 12 and the first electrode layer 51 can be reduced. Thus, the area of the light emitting region can be increased. Hence, the semiconductor light emitting device 110 with high light emission efficiency can be manufactured.

### Second Embodiment

Next, a second embodiment is described.

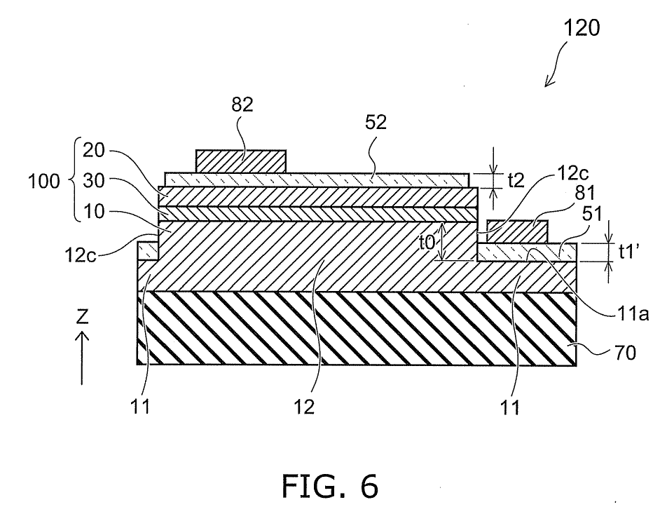

FIG. 6 is a schematic sectional view illustrating the configuration of a semiconductor light emitting device according to a second embodiment.

As shown in FIG. 6, in the semiconductor light emitting device 120 according to the embodiment, the thickness t1′ of the first electrode layer 51 is greater than or equal to the thickness t2 of the second electrode layer 52. The thickness t1′ is thinner than the thickness t0 of the side surface 12c portion of the second portion 12.

The thickness t1′ of the first electrode layer 51 in this semiconductor light emitting device 120 is thicker than the thickness t1 of the first electrode layer 51 in the semiconductor light emitting device 110 according to the first embodiment. Hence, in the semiconductor light emitting device 120, the sheet resistance of the first electrode layer 51 can be made lower than that in the semiconductor light emitting device 110. This achieves further improvement in light emission efficiency.

A method for manufacturing the semiconductor light emitting device 120 according to the second embodiment is described.

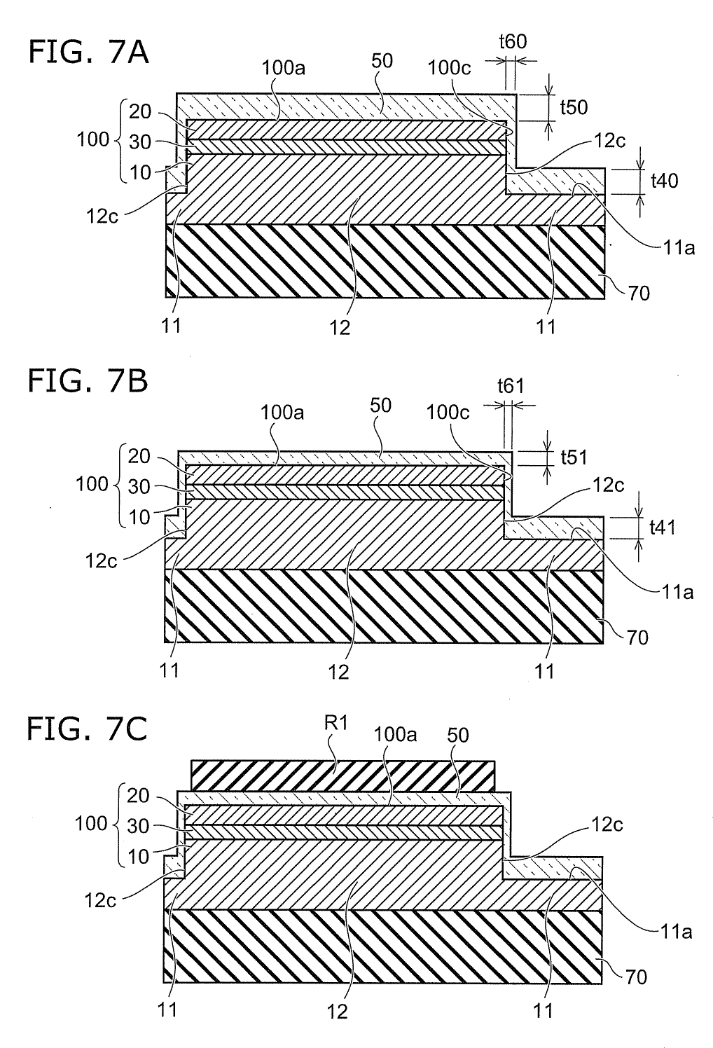

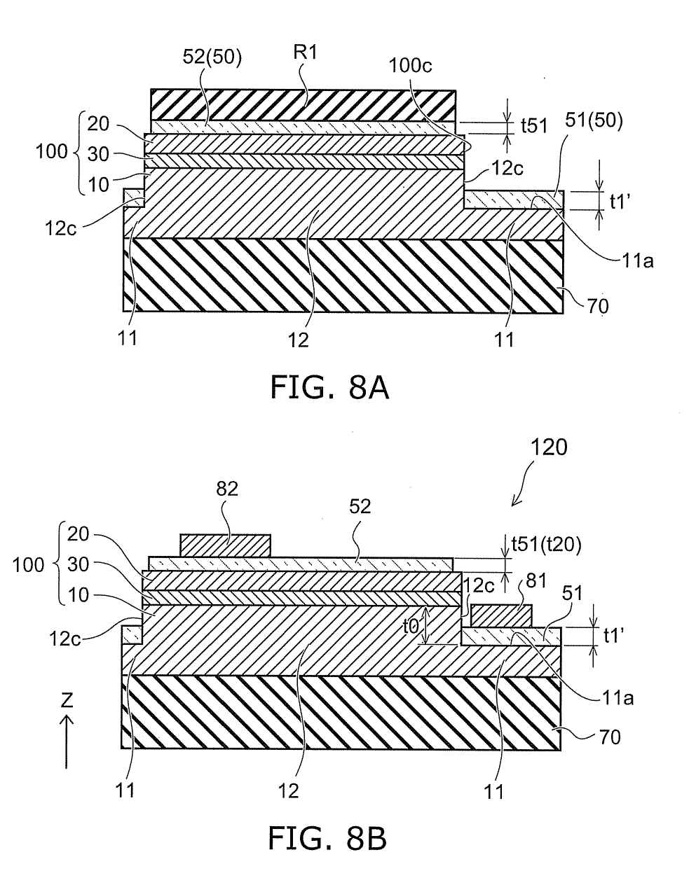

FIGS. 7A to 8B are schematic sectional views illustrating the method for manufacturing the semiconductor light emitting device.

In this manufacturing method, the process of forming a stacked body 100 by crystal growth of a first semiconductor layer 10, a light emitting layer 30, and a second semiconductor layer 20 on a substrate 70, and the process of forming a mesa structure by etching the stacked body 100 are similar to those of the first embodiment illustrated in FIGS. 3A and 3B.

Next, as shown in FIG. 7A, an electrode material 50 is film-formed entirely on the surface of the stacked body 100 and the exposed surface of the first semiconductor layer 10. Like the foregoing, the electrode material 50 is made of e.g. ITO. The film thickness of the electrode material 50 is t40 on the first semiconductor layer 10, t50 on the upper surface 100a of the stacked body 100, and t60 on the side surface of the stacked body 100.

The film thicknesses t40 and t50 are nearly equal. The film thickness t60 is thinner than the film thicknesses t40 and t50. In the embodiment, the film thickness of the electrode material 50 is preferably made thicker than the film thickness of the electrode material 50 in the first embodiment shown in FIG. 3C.

Next, as shown in FIG. 7B, the entire surface of the electrode material 50 thus formed is etched. In this etching, for instance, wet etching is used. As an etchant for ITO, for instance, a liquid mixture of HCl and HNO₃ is used.

Here, as described above, in the etching of the electrode material 50, the etching rate of the electrode material 50 formed on the second semiconductor layer 20 is higher than the etching rate of the electrode material 50 formed on the first semiconductor layer 10 exposed in the first portion 11. Hence, by the entire surface etching of the electrode material 50, the film thickness t51 (second film thickness) of the electrode material 50 left on the second semiconductor layer 20 is made thinner than the film thickness t41 (first film thickness) of the electrode material 50 on the first semiconductor layer 10. That is, the film thickness t41 is made thicker than the film thickness t51.

Next, as shown in FIG. 7C, a resist pattern R1 is formed on the second semiconductor layer 20 constituting the upper surface 100a of the stacked body 100. Then, this resist pattern R1 is used as a mask to etch the electrode material 50.

By the difference in etching rate as described above, the portion of the electrode material 50 on the second semiconductor layer 20 not covered with the resist pattern R1 is etched more rapidly than the electrode material 50 on the first semiconductor layer 10. Thus, even if this portion is removed, the electrode material 50 on the first semiconductor layer 10 is left.

Furthermore, the electrode material 50 formed on the side surface 100c of the stacked body 100 is thinner than the electrode material 50 on the first semiconductor layer 10, and hence is removed earlier than the electrode material 50 on the first semiconductor layer 10.

This etching removes the electrode material 50 on the second semiconductor layer 20 not covered with the resist pattern R1 and the electrode material 50 formed on the side surface 100c of the stacked body 100.

As shown in FIG. 8A, by this etching, the electrode material 50 left on the first semiconductor layer 10 constitutes a first electrode layer 51, and the electrode material 50 on the second semiconductor layer 20 covered with the resist pattern R1 constitutes a second electrode layer 52. By the removal of the electrode material 50 formed on the side surface 100c, the first electrode layer 51 and the second electrode layer 52 are separated from each other.

The thickness of the first electrode layer 51 formed by this etching is t1′. On the other hand, the thickness of the second electrode layer 52 remains t51. The thickness t1′ of the first electrode layer 51 is made thinner than the film thickness t41 before etching, but is greater than or equal to the thickness t51 of the second electrode layer 52. That is, the difference between the film thickness t41 of the electrode material 50 before etching and the film thickness t51 is set to be greater than or equal to the amount of decrease by etching (the difference between t41 and t1′). Thus, the thickness t1′ of the first electrode layer 51 can be made greater than or equal to the thickness t51 of the second electrode layer 52. Here, the thickness t51 is equal to the thickness t2 shown in FIG. 6.

After etching the electrode material 50, the resist pattern R1 is removed.

Subsequently, as shown in FIG. 8B, a first metal electrode 81 is formed on the first electrode layer 51, and a second metal electrode 82 is formed on the second electrode layer 52. Thus, the semiconductor light emitting device 120 is completed.

This manufacturing method can adjust the difference between the thickness t1′ of the first electrode layer 51 and the thickness t51 of the second electrode layer 52 by adjusting the amount of entire surface etching of the electrode material 50 in the process shown in FIG. 7B. Thus, the balance of sheet resistance between the first electrode layer 51 and the second electrode layer 52 can be adjusted. Hence, the semiconductor light emitting device 120 with high light emission efficiency can be manufactured.

### Third Embodiment

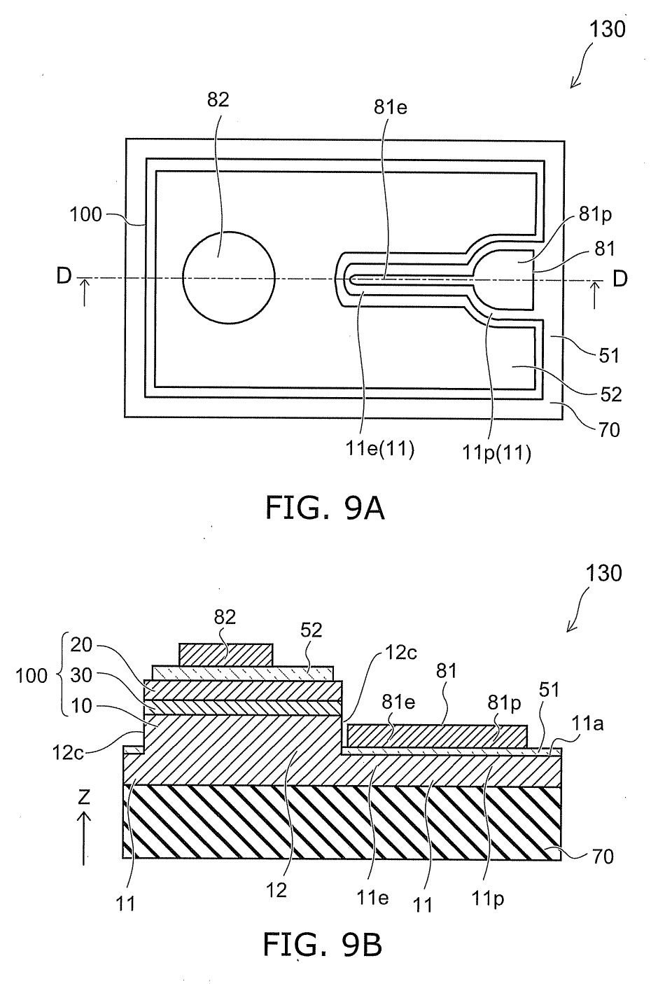

FIGS. 9A and 9B are schematic views illustrating the configuration of a semiconductor light emitting device according to a third embodiment.

More specifically, FIG. 9A is a schematic plan view of the semiconductor light emitting device 130 according to the embodiment. FIG. 9B is a schematic sectional view taken along line D-D shown in FIG. 9A.

As shown in FIGS. 9A and 9B, in the semiconductor light emitting device 130 according to the third embodiment, the first portion 11 includes a pad portion 11p and an extended portion 11e. The first metal electrode 81 includes a pad electrode portion 81p and an extended electrode portion 81e.

The extended portion 11e is provided along the direction from the first metal electrode 81 to the second metal electrode 82 along the major surface 11a.

The pad electrode portion 81p is provided on the pad portion 11p. The extended electrode portion 81e is provided on the extended portion 11e.

The extended electrode portion 81e has a slimmer shape than the pad electrode portion 81p, and is provided so as to extend in the direction from the pad electrode portion 81p to the second metal electrode 82.

The first electrode layer 51 is provided on the pad portion 11p and the extended portion 11e in the first portion 11. Even in such a configuration including the extended electrode portion 81e, the first electrode layer 51 is formed in contact with the side surface 12c of the second portion 12.

The semiconductor light emitting device 130 can be manufactured as follows. In the process shown in FIG. 3B, the mask for etching the stacked body 100 into a mesa structure is shaped to include an opening corresponding to the pad portion 11p and the extended portion 11e. Furthermore, in the process shown in FIG. 4C, the first metal electrode 81 is shaped in conformity with the shape of the pad electrode portion 81p and the extended electrode portion 81e.

The extended electrode portion 81e of the first metal electrode 81 functions as a so-called thin wire electrode. This can alleviate current concentration between the first metal electrode 81 and the second metal electrode 82, and enables uniform light emission.

In the configuration including the extended portion 11e and the extended electrode portion 81e as in the semiconductor light emitting device 130, the peripheral length of the outline of the second portion 12 is longer than that in the semiconductor light emitting devices 110 and 120 lacking such configuration.

In the semiconductor light emitting device 130 according to the embodiment, the first electrode layer 51 is in contact with the side surface 12c of the second portion 12. Thus, the gap between the first electrode layer 51 and the side surface 12c can be reduced. Hence, even if the peripheral length of the second portion 12 is made longer, there is no influence of area reduction of the light emitting region.

Here, the shape and the number of portions of the extended portion 11e and the extended electrode portion 81e are not limited to the foregoing. For instance, a plurality of extended portions 11e and extended electrode portions 81e may be provided from the pad portion 11p and the pad electrode portion 81p. Alternatively, from one extended portion 11e and extended electrode portion 81e, other extended portions 11e and extended electrode portions 81e may be branched.

As described above, the semiconductor light emitting device and the method for manufacturing the same according to the embodiments can achieve improvement in light emission efficiency and simplification of the manufacturing process.

The embodiments and the variations thereof have been described above. However, the invention is not limited to these examples. For instance, in the above description of the embodiments, the first conductivity type is n-type, and the second conductivity type is p-type. However, the invention is also applicable to the case where the first conductivity type is p-type and the second conductivity type is n-type. Furthermore, in the examples described above, the stacked body 100 is made of nitride semiconductors. However, the invention is also applicable to semiconductors other than nitride semiconductors. Furthermore, those skilled in the art can modify the above embodiments or the variations thereof by suitable addition, deletion, and design change of components, and by suitable combination of the features of the embodiments. Such modifications are also encompassed within the scope of the invention as long as they fall within the spirit of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a first semiconductor layer of a first conductivity type including a first portion and a second portion thicker than the first portion, the second portion including a side surface rising from a major surface of the first portion;
a light emitting layer provided on the second portion;
a second semiconductor layer of a second conductivity type provided on the light emitting layer, the second conductivity type being different from the first conductivity type;
a first electrode layer provided along the major surface of the first portion and being in contact with the side surface of the second portion; and
a second electrode layer provided on the second semiconductor layer.

2. The device according to claim 1, wherein
the first electrode layer is formed from a translucent material transmitting light emitted from the light emitting layer, and
the second electrode layer is formed from the translucent material transmitting light emitted from the light emitting layer.

3. The device according to claim 1, wherein a thickness of the first electrode layer with reference to the major surface is thinner than a thickness of the second portion with reference to the major surface.

4. The device according to claim 1, wherein the first electrode layer is formed so as to surround the second electrode layer as viewed in a direction connecting the first semiconductor layer and the second semiconductor layer.

5. The device according to claim 1, wherein a thickness of the first electrode layer is thinner than a thickness of the second electrode layer.

6. The device according to claim 1, wherein a thickness of the first electrode layer is greater than or equal to a thickness of the second electrode layer.

7. The device according to claim 1, wherein
the first electrode layer includes indium tin oxide, and
the second electrode layer includes indium tin oxide.

8. The device according to claim 1, wherein the first semiconductor layer, the light emitting layer, and the second semiconductor layer include a nitride semiconductor.

9. A method for manufacturing a semiconductor light emitting device, comprising:
forming a stacked body by sequentially stacking a first semiconductor layer of a first conductivity type, a light emitting layer, and a second semiconductor layer of a second conductivity type;
removing a part of the stacked body from the second semiconductor layer to halfway through the first semiconductor layer to form an exposed portion where the first semiconductor layer is exposed and a stacked portion except the exposed portion;
forming an electrode layer on a surface of the exposed portion and a surface of the stacked portion;
forming a mask on the electrode layer on the stacked portion; and
etching the electrode layer through the mask to separate the electrode layer into a first electrode layer left on the exposed portion and a second electrode layer left on a portion covered with the mask, a thickness of the second electrode layer being different from a thickness of the first electrode layer.

10. The method according to claim 9, wherein the thickness of the first electrode layer is made thinner than the thickness of the second electrode layer.

11. The method according to claim 9, wherein the thickness of the first electrode layer is made greater than or equal to the thickness of the second electrode layer.

12. The method according to claim 9, wherein the electrode layer is made of a translucent material transmitting light emitted from the light emitting layer.

13. The method according to claim 9, wherein the electrode layer is made of a material including indium tin oxide.

14. The method according to claim 9, wherein the electrode layer is formed so that a film thickness of the electrode layer formed on a side surface of the stacked portion is thinner than a film thickness of the electrode layer formed on the surface of the exposed portion.

15. The method according to claim 9, further comprising, after forming the electrode layer on the surface of the exposed portion and the surface of the stacked portion, and before forming the mask,
etching the electrode layer to provide a difference between a first film thickness which is a film thickness of the electrode layer on the exposed portion and a second film thickness which is a film thickness of the electrode layer on the stacked portion.

16. The method according to claim 15, wherein the first film thickness is thicker than the second film thickness.

17. The device according to claim 2, further comprising, a first metal electrode on the first electrode layer, and a second metal electrode on the second electrode layer, the first metal electrode being not contact with the side surface of the second portion.

18. The device according to claim 17, wherein a thickness of the first electrode layer with reference to the major surface is thinner than a thickness of the second portion with reference to the major surface.

19. The device according to claim 17, wherein the first electrode layer is formed so as to surround the second electrode layer as viewed in a direction connecting the first semiconductor layer and the second semiconductor layer.

20. The device according to claim 17, wherein a thickness of the first electrode layer is thinner than a thickness of the second electrode layer.
